(19) United States
(12) Patent Application Publication
(10) Pub. No.: US 2026/0190303 A1
(43) Pub. Date: Jul. 2, 2026

(54) HEAT SINK WITH PRESSURE LOSS-OPTIMIZED ARRANGEMENT OF COOLING PINS WITHIN THE COOLING CHANNEL

(71) Applicant: TRUMPF Hüttinger GmbH + Co. KG, Freiburg (DE)

(72) Inventors: Guido Dieter Hodapp, Emmendingen (DE); Felix Mussler, Hohberg (DE)

(21) Appl. No.: 19/550,360

(22) Filed: Feb. 26, 2026

Related U.S. Application Data
(63) Continuation of application No. PCT/EP2024/074228, filed on Aug. 29, 2024.

(30) Foreign Application Priority Data
Sep. 1, 2023 (DE) 10 2023 123 660.1

(51) Int. Cl. H05K 7/20

(52) U.S. Cl. CPC H05K 7/209; H05K 7/20927

(57) ABSTRACT

A heat sink for cooling an electric unit to be cooled, including a cooling channel through which cooling liquid is configured to flow. The cooling channel has a first cooling wall on a side of the cooling channel facing the electric unit to be cooled. The heat sink further includes a plurality of cooling pins arranged in the cooling channel, the plurality of cooling pins extending from the first cooling wall into the cooling channel. The plurality of cooling pins includes at least one cooling pin of a first category which is oriented in a first inclination direction, the first inclination direction being inclined obliquely relative to a perpendicular to the first cooling wall. The plurality of cooling pins are arranged such that each respective cooling pin of the plurality of cooling pins does not intersect any other cooling pin of the plurality of cooling pins.

### CROSS REFERENCE TO RELATED APPLICATIONS

This application is a continuation of International Application No. PCT/EP2024/074228 (WO 2025/046036 A1), filed on August 29, 2024, and claims benefit to German Patent Application No. DE 10 2023 123 660.1, filed on September 1, 2023. The aforementioned applications are hereby incorporated by reference herein.

### FIELD

The invention relates to a heat sink for cooling a unit to be cooled, to a method for designing a heat sink for cooling a unit to be cooled, to a method for producing a heat sink for cooling a unit to be cooled, and to an electrical power converter for an industrial process assembly.

### BACKGROUND

The present disclosure relates to the field of electrical power conversion for special power-intensive and instability-prone industrial processes, such as plasma excitation, plasma coating processes, gas laser excitation, particle accelerators, charging and discharging systems for large batteries, such as flow batteries, melting of solids, heating and/or gasification of liquids by, for example, microwave energy or induction heating. All these processes have in common that they are designed to generate and accelerate charged atomic particles in a gas and/or plasma environment or liquid. All these processes also have in common that they have a high power consumption, which is in the range of 1 kW or more, in particular 10 kW or more, preferably 100 kW or more. Many of these processes also have a very high requirement for the stability of the power supply because the processes are highly complex, such as semiconductor manufacturing using plasma processes and/or heating by electromagnetic fields. Typically, power is converted from a mains frequency, which is in the range of approximately 50 Hz to 60 Hz, to different frequencies, which can range from 1 kHz to 200 MHz. Conversion to direct current power, also called DC power, can also be provided. Converting electrical power to other frequencies requires a plurality of electronic components and modules, in particular power semiconductor components such as transistors or diodes designed for currents ≥ 10 A and voltages ≥ 400 V. These electronic components and modules generate waste heat during operation. The waste heat often arises over a very limited area of just a few mm². It presents a particular challenge to dissipate this waste heat in order to protect the components and/or modules from destruction due to overheating. Often, very large and material-intensive heat sinks are provided for this purpose, the production of which is very expensive.

In the prior art, the heat energy is dissipated by cooling using a cooling plate. When cooling with such a conventional cooling plate, the heat transfer from the electrical component, which may have a copper layer, to the cooling medium is achieved by applying a material, such as thermal paste, to the thermal interface, thereby dissipating the generated heat. Such heat interface material proves to be disadvantageous. Firstly, it represents another heat transfer with thermal resistance, and secondly, it is subject to wear, which gradually deteriorates its effectiveness during operation. The area of the cooling plate is also increased or the number and performance of the components are reduced in order to dissipate a larger amount of heat or generate a small amount of heat. Both options prove to be insufficient. Since the installation space in the housing of such a power supply is limited, an expansion of the cooling area is not possible indefinitely. Reducing the performance of individual components is also not expedient. Overall, the inadequate cooling of the electrical components results in costs.

### SUMMARY

In an embodiment, the present disclosure provides a heat sink for cooling an electric unit to be cooled, the heat sink comprising a cooling channel through which cooling liquid is configured to flow in an intended flow direction. The cooling channel has a first cooling wall on a side of the cooling channel facing the electric unit to be cooled. The heat sink further comprises a plurality of cooling pins arranged in the cooling channel or in a sub-region of the cooling channel, the plurality of cooling pins extending from the first cooling wall into the cooling channel. The plurality of cooling pins comprises at least one cooling pin of a first category which is oriented in a first inclination direction, the first inclination direction being inclined obliquely relative to a perpendicular to the first cooling wall. The plurality of cooling pins are arranged such that each respective cooling pin of the plurality of cooling pins does not intersect any other cooling pin of the plurality of cooling pins.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a heat sink together with a unit to be cooled in longitudinal section;

FIG. 2 shows a distribution unit and a circuit board which has recesses for a plurality of units to be cooled;

FIG. 3 shows an industrial process assembly, preferably a plasma process assembly or a heating assembly with a heat sink;

FIG. 4 shows a cooling channel of a heat sink in which a plurality of cooling pins are arranged;

FIG. 4A shows an oblique view of a cooling pin of a first category;

FIG. 4B shows a view of the cooling pin of the first category in a first projection plane;

FIG. 4C shows a view of the cooling pin of the first category in a second projection plane;

FIG. 5A shows an oblique view of a cooling pin of a second category;

FIG. 5B shows a view of the cooling pin of the second category in a first projection plane;

FIG. 5C shows a view of the cooling pin of the second category in a second projection plane;

FIG. 6 shows an oblique view of a cooling pin of a third category;

FIG. 7 shows an oblique view of a cooling pin of a fourth category;

FIG. 8 shows an embodiment in which cooling pins of a first category are arranged along a first straight line and cooling pins which are mirror-inverted with respect thereto are arranged along a second straight line;

FIG. 9A shows a unit cell within which a second plurality of cooling pins is arranged; and

FIG. 9B shows a cooling channel in which a plurality of identical unit cells are arranged adjacent to each other in a sub-region of the cooling channel.

### DETAILED DESCRIPTION

Heat sinks are intended to dissipate heat that arises during the operation of a unit to be cooled. For this purpose, heat sinks have a cooling channel through which coolant, in particular cooling liquid, preferably cooling water, can flow. To achieve high cooling performance, it is advantageous to design the interior of the cooling channel in such a way that close thermal contact is formed between the heat sink and the coolant. However, the interior of the cooling channel should be designed in such a way that the pressure loss of the coolant flowing through the cooling channel does not become too great.

In an embodiment, the present disclosure provides a heat sink that enables good heat transfer from the heat sink to the coolant with low pressure loss of the coolant flowing through the cooling channel.

The foregoing can be achieved by using a heat sink to cool a unit to be cooled, in particular an electric unit, preferably a semiconductor assembly. This unit to be cooled, in particular an electric unit, preferably of a semiconductor assembly, can in particular be part of an electrical power converter for converting electrical power from the power supply network into electrical power ≥ 1 kW for supplying an industrial process, in particular a plasma processing process, a laser excitation or heating process by means of electromagnetic power.

The semiconductor assembly can in particular have a power semiconductor component, wherein the power converter is designed such that the power semiconductor device can be operated in switching or amplifier mode at a frequency greater than 20 kHz and can generate an electrical power loss of ≥ 500 W. The heat sink has a cooling channel through which coolant, in particular cooling liquid, preferably cooling water, can flow in an intended flow direction, wherein the cooling channel has a first cooling wall on the side of the cooling channel facing the unit to be cooled. In the cooling channel or in a sub-region of the cooling channel, a plurality of cooling pins are arranged, extending from the first cooling wall into the cooling channel. The plurality of cooling pins comprises at least one cooling pin of a first category, which is oriented in a first inclination direction that is inclined obliquely relative to a perpendicular to the first cooling wall. The cooling pins of the plurality of cooling pins are arranged such that a cooling pin of the plurality of cooling pins does not intersect another cooling pin of the plurality of cooling pins.

In the heat sink, a plurality of cooling pins are arranged in the cooling channel or in a sub-region of the cooling channel and extend from the first cooling wall into the cooling channel. A cooling pin is a cooling element which has a length that is greater than the average width or diameter of the cooling element. In particular, a cooling pin can, for example, be designed with a cylindrical or a tapered geometry. The directional extension of the cooling pin can preferably be represented by means of a center line of the cooling pin. According to an exemplary embodiment, for determining such a center line, for example, a line can be laid through the centers of the cross-sections along the cooling pin. The center line of a cooling pin can, for example, be designed as a straight line, but it can also be slightly curved or slightly bent.

In an aspect, at least the cooling pins of the first category are oriented in manner inclined obliquely with respect to a perpendicular to the first cooling wall. The term "inclined obliquely" here means that the cooling pins of the first category are neither parallel nor perpendicular to the first cooling wall. It was found that the oblique arrangement of the cooling pins allows for particularly good coolant flow around and improved thermal contact between the cooling pin and the coolant.

In an aspect, the cooling pins of the plurality of cooling pins are arranged in such a way that no cooling pin intersects any other cooling pin of the plurality of cooling pins. This non-intersecting arrangement of the cooling pins in the cooling channel or in a sub-region of the cooling channel results in improved flow through the cooling channel and a reduction in pressure loss. The pressure required to pump the coolant through the cooling channel has turned out to be particularly low in the solution according to the present disclosure.

In an aspect, an electrical power converter is disclosed for an industrial process assembly, preferably a plasma process assembly or a heating assembly, having:

a heat sink, as described above and below,

a circuit board,

a unit to be cooled, in particular an electric unit, preferably a semiconductor assembly, preferably having a power semiconductor component,

further electronic components, wherein the further electronic components and the unit to be cooled are arranged on or against a printed circuit board and are connected to electrical contacts, wherein the unit to be cooled has a fixed, in particular integrally bonded, connection to the heat sink.

A preferred outcome of the development is to realize the connection between the unit to be cooled and the heat sink with as little additional material and to be as thin as possible. With the considerations, simulations and experiments for this development, it was found that this is particularly made possible when the heat sink through which fluid flows is fixedly connected, in particular in an integrally bonded manner, to the unit to be cooled. This can be done, for example, by a soldered connection, sintering, pressing or 'direct copper bonding' (DCB). The term 'fixedly' here can mean: 'only destructively detachable'. This means using means of connection that cannot be detached even with tools without destroying either the unit to be cooled or the heat sink or both components.

In an aspect, a method is disclosed for the design of a heat sink for cooling a unit to be cooled. The heat sink has a cooling channel through which coolant can flow in an intended flow direction, and the cooling channel has a first cooling wall on the side of the cooling channel facing the unit to be cooled. The method comprises arranging a plurality of cooling pins in the cooling channel, which extend from the first cooling wall into the cooling channel. The plurality of cooling pins comprises at least one cooling pin of a first category, which is oriented in a first inclination direction that is inclined obliquely relative to a perpendicular to the first cooling wall. The cooling pins of the plurality of cooling pins are arranged such that a cooling pin of the plurality of cooling pins does not intersect another cooling pin of the plurality of cooling pins.

In an aspect, a further method is disclosed for producing a heat sink for cooling a unit to be cooled. The heat sink has a cooling channel through which coolant can flow in an intended flow direction, and the cooling channel has a first cooling wall on the side of the cooling channel facing the unit to be cooled. The method comprises producing a plurality of cooling pins within the cooling channel, which extend from the first cooling wall into the cooling channel, by means of an additive process. The plurality of cooling pins comprises at least one cooling pin of a first category, which is oriented in a first inclination direction that is inclined obliquely relative to a perpendicular to the first cooling wall. The cooling pins of the plurality of cooling pins are arranged such that a cooling pin of the plurality of cooling pins does not intersect another cooling pin of the plurality of cooling pins.

Advantageous embodiments and developments, which can be used individually or in combination, are the subject of the following description.

In an aspect, each cooling pin of the plurality of cooling pins is arranged in such a way that coolant can flow completely around it. This enables high heat transfer from the cooling pins to the coolant.

It is advantageous if the cooling pins of the plurality of cooling pins are arranged in such a way that a cooling pin of the plurality of cooling pins does not touch another cooling pin of the plurality of cooling pins. This creates a spacing between the cooling pins. This facilitates the flow through the cooling channel; the pressure loss is reduced.

In an aspect, viewed in a first projection direction, the first inclination direction is inclined obliquely with respect to the perpendicular to the first cooling wall, the first projection direction being the intended flow direction of the coolant, and also viewed in a second projection direction, the first inclination direction is inclined obliquely with respect to the perpendicular to the first cooling wall, the second projection direction being orthogonal both to the intended flow direction and to the perpendicular to the first cooling wall. This oblique orientation of the cooling pin, viewed both in the projection direction and in the second projection direction, results in an advantageous flow pattern in the cooling channel, which on the one hand reduces the flow resistance in the cooling channel and on the other hand enables efficient heat transfer from the cooling pins to the coolant.

In an aspect, viewed in a first projection direction, the first inclination direction in a first projection plane is inclined obliquely with respect to the perpendicular to the first cooling wall, the first projection direction being the intended flow direction of the coolant and the first projection plane being the plane perpendicular to the first projection direction, and also viewed in a second projection direction, the first inclination direction in a second projection plane is inclined obliquely with respect to the perpendicular to the first cooling wall, the second projection direction being orthogonal both to the intended flow direction and to the perpendicular to the first cooling wall, and the second projection plane being the plane perpendicular to the second projection direction. In both the first and second projection planes, the cooling pin is oriented in an obliquely inclined manner.

In an aspect, viewed in the first projection direction, the first inclination direction in the first projection plane is inclined at a first angle with respect to the perpendicular to the first cooling wall. Preferably, the first angle is a positive or negative angle in the range between 0° and 90°, more preferably in the range between 10° and 80°, more preferably in the range between 20° and 70°, more preferably in the range between 30° and 60°, more preferably in the range between 35° and 55°, more preferably in the range between 40° and 50°.

In an aspect, the first angle is a positive or negative angle of approximately 45°. An orientation at an angle of approximately 45° has proven particularly advantageous in improving heat transfer from the cooling pin to the coolant and reducing the pressure loss of the coolant flowing through the cooling channel.

In an aspect, viewed in the second projection direction, the first inclination direction in the second projection plane is inclined at a second angle with respect to the perpendicular to the first cooling wall. Preferably, the second angle is a positive or negative angle in the range between 0° and 90°, more preferably in the range between 10° and 80°, more preferably in the range between 20° and 70°, more preferably in the range between 30° and 60°, more preferably in the range between 35° and 55°, more preferably in the range between 40° and 50°.

It is advantageous if the second angle is a positive or negative angle of approximately 45°. This improves the heat transfer from the cooling pin to the coolant and reduces the pressure loss of the coolant flowing through the cooling channel.

In an aspect, the plurality of cooling pins comprises at least one cooling pin of a second category which is oriented in a second inclination direction which is inclined obliquely relative to the perpendicular to the first cooling wall, the second inclination direction being different from the first inclination direction. In this embodiment, the plurality of pins comprises cooling pins of the first category, which are oriented in a first inclination direction, and cooling pins of the second category, which are oriented in a second inclination direction. The different orientations of the cooling pins create a flow pattern in the cooling channel that has proven advantageous for efficient heat dissipation.

In an aspect, viewed in a first projection direction, the second inclination direction is inclined obliquely with respect to the perpendicular to the first cooling wall, the first projection direction being the intended flow direction of the coolant, and also viewed in a second projection direction, the second inclination direction is inclined obliquely with respect to the perpendicular to the first cooling wall, the second projection direction being orthogonal both to the intended flow direction and to the perpendicular to the first cooling wall. The cooling pins of the second category are also oriented in an obliquely inclined manner when viewed in both the first and second projection directions.

In an aspect, viewed in the first projection direction, the second inclination direction in a first projection plane is inclined by a third angle with respect to the perpendicular to the first cooling wall, the first projection plane being the plane perpendicular to the first projection direction. Preferably, the third angle is a positive or negative angle in the range between 0° and 90°, more preferably in the range between 10° and 80°, more preferably in the range between 20° and 70°, more preferably in the range between 30° and 60°, more preferably in the range between 35° and 55°, more preferably in the range between 40° and 50°.

In an aspect, viewed in the second projection direction, the second inclination direction in the second projection plane is inclined by a fourth angle with respect to the perpendicular to the first cooling wall, the second projection plane being the plane perpendicular to the second projection direction. Preferably, the fourth angle is a positive or negative angle in the range between 0° and 90°, more preferably in the range between 10° and 80°, more preferably in the range between 20° and 70°, more preferably in the range between 30° and 60°, more preferably in the range between 35° and 55°, more preferably in the range between 40° and 50°.

In an aspect, a plurality of cooling pins of the first category are arranged along a first straight line that runs along the first cooling wall. In this embodiment, a plurality of cooling pins with a matching orientation are arranged along a straight line. The resulting structure of a plurality of cooling pins spaced apart and oriented in the same direction enables effective heat transfer to the flowing coolant with low flow resistance.

In an aspect, viewed in a third projection direction, the first inclination direction is inclined obliquely at a fifth angle with respect to the perpendicular to the first cooling wall, the third projection direction being the direction of the first straight line, and viewed in a fourth projection direction, the first inclination direction is inclined obliquely at a sixth angle with respect to the perpendicular to the first cooling wall, the fourth projection direction being orthogonal both to the first straight line and to the perpendicular to the first cooling wall.

In an aspect, the plurality of cooling pins comprises a plurality of cooling pins which are mirror-inverted with respect to the cooling pins of the first category and which are oriented in an inclination direction which is mirror-inverted with respect to the first inclination direction, a plurality of the cooling pins which are mirror-inverted with respect to the cooling pins of the first category being arranged along a second straight line that runs parallel to the first straight line along the first cooling wall. In this embodiment, a plurality of cooling pins which are mirror-inverted with respect to the cooling pins of the first category are arranged along a second straight line. The opposite rows of cooling pins further improve heat transfer to the coolant.

In an aspect, viewed in the third projection direction, the inclination direction which is mirror-inverted with respect to the first inclination direction is inclined obliquely at a seventh angle with respect to the perpendicular to the first cooling wall, the third projection direction being the direction of the first straight line, and viewed in the fourth projection direction, the inclination direction which is mirror-inverted with respect to the first inclination direction is inclined obliquely at an eighth angle with respect to the perpendicular to the first cooling wall, the fourth projection direction being orthogonal both to the first straight line and to the perpendicular to the first cooling wall, and the seventh angle corresponding to the fifth angle with a negative sign and the eighth angle corresponding to the sixth angle.

In an aspect, a plurality of identical unit cells are arranged in the cooling channel or in the sub-region of the cooling channel, wherein a second plurality of cooling pins are arranged within a unit cell, which are intended to extend from the first cooling wall into the cooling channel. Using such a unit cell simplifies the design of a heat sink.

In an aspect, the cooling pins of the second plurality of cooling pins within the unit cell are arranged such that a cooling pin of the second plurality of cooling pins does not intersect any other cooling pin of the second plurality of cooling pins. Avoiding intersections between cooling pins ensures low flow resistance in the cooling channel.

In an aspect, a unit cell comprises at least one cooling pin of the first category, which is oriented in the first inclination direction inclined obliquely relative to the perpendicular to the first cooling wall, and at least one cooling pin of a second category, which is oriented in a second inclination direction inclined obliquely relative to the perpendicular to the first cooling wall, the second inclination direction being different from the first inclination direction. The cooling pins of different orientations provided by the unit cell ensure effective heat dissipation.

It is advantageous if the cooling channel or the sub-region of the cooling channel is filled by a plurality of adjacent unit cells. The repeating arrangement of unit cells in the cooling channel simplifies and accelerates the design and production of the heat sink.

In an aspect, the plurality of unit cells arranged in a plurality of rows and/or in a plurality of columns fills the cooling channel or a sub-region of the cooling channel.

In an aspect, the height of the unit cell corresponds to the height of the cooling channel. This adapts the geometry of the unit cell to the geometry of the cooling channel. The cooling channel can be filled by adjacent unit cells.

In an aspect, the unit cell is cuboid in shape. The cuboid shape of the unit cell simplifies the filling of the cooling channel with adjacent unit cells.

It is advantageous if the unit cell serves as the basic design unit for the design of the heat sink. Once the unit cell is designed, the heat sink can be manufactured.

In an aspect, the cooling pins are rod-like. More preferably, the cooling pins preferably have a substantially cylindrical shape. The rod-like or cylindrical design of the cooling pins creates a large contact surface for heat transfer from the cooling pins to the coolant.

In an aspect, the cooling pins have a round or oval cross-section. This can further reduce flow resistance.

It is advantageous if the cooling channel has a second cooling wall on the side of the cooling channel opposite the first cooling wall.

In an aspect, the cooling pins of the plurality of cooling pins extend continuously from the first cooling wall to the second cooling wall. In this way, heat can be supplied to the cooling pins from both the first cooling wall and the second cooling wall. This results in improved heat dissipation.

In an aspect, the first cooling wall is arranged substantially parallel to the second cooling wall. The parallel orientation of the first cooling wall and the second cooling wall ensures a homogeneous flow through the cooling channel with turbulent flow conditions inside.

It is advantageous if the cooling channel has a substantially constant cross-section across the entire heat sink. This results in a constant flow rate of the coolant across the cooling channel. This is advantageous with a local dependence of the flow rate, leading to a desired turbulent system.

In an aspect, the cooling channel has a substantially rectangular cross-section. Furthermore, it is advantageous if the cooling channel is designed as a substantially cuboid cooling channel. Such geometries simplify the formation of flat contact areas for thermal contacting of the units to be cooled.

It is advantageous if the heat sink is a micro heat sink and the unit to be cooled is an electronic component. According to this embodiment, a separate micro heat sink can be provided for each electronic component. This enables heat dissipation that is individually adapted to the electronic component. Preferably, the unit to be cooled is an electronics module.

In an aspect, the heat sink comprises an inlet, and coolant can be supplied via the inlet at a first end of the cooling channel. More preferably, the heat sink comprises an outlet, and coolant can be discharged via the outlet at a second end of the cooling channel, the second end of the cooling channel being arranged opposite the first end of the cooling channel. This ensures that the coolant flows through the entire heat sink.

In an aspect, the heat sink consists of or comprises metal. Metals generally have high thermal conductivity. According to a preferred embodiment, the heat sink consists of or comprises copper. Copper is a metal with very high thermal conductivity and is therefore preferred for the construction of heat sinks. According to an alternative preferred embodiment, the heat sink consists of or comprises one of molybdenum, stainless steel and nickel.

In an aspect, the cooling pins of the heat sink are produced by means of an additive manufacturing process, in particular selective laser melting (SLM). Using such additive manufacturing processes, the cooling pins can be applied to the first cooling wall of the heat sink in virtually any orientation. Even in additive manufacturing, certain restrictions must be observed regarding the structure, e.g. internally, such as the build angle, which in particular should be less than 45°, otherwise it would not be possible without a support structure.

In an aspect, the plurality of cooling pins are arranged such that a cooling pin of the first category overlaps with a cooling pin of the second category at a viewing angle parallel to the cooling wall, in particular at a viewing angle of the coolant flow direction. "Overlapping" here means that at least one cooling pin of the first category at least partially covers another cooling pin of the second category in the given viewing direction. Such an assembly can improve the turbulence of the coolant at the cooling pins and consequently the heat transfer from the cooling pins to the coolant.

In an aspect, the plurality of cooling pins are arranged in such a way that a cooling pin of the first category is interweaved with two cooling pins of the second category at a viewing angle parallel to the cooling wall, in particular at a viewing angle of the coolant flow direction. The term "interweaved" here means that at least one first cooling pin of the first category at least partially covers a second cooling pin of the second category in the given viewing direction, and that the first cooling pin itself is also at least partially covered by a further cooling pin of the second category in the given viewing direction. Such an arrangement can further improve the turbulence of the coolant at the cooling pins and consequently the heat transfer from the cooling pins to the coolant.

Further advantageous embodiments are described in more detail below with reference to several exemplary embodiments shown in the drawings, to which the development is not limited, however.

In the following description of preferred embodiments of the present disclosure, identical reference signs denote the same or similar components.

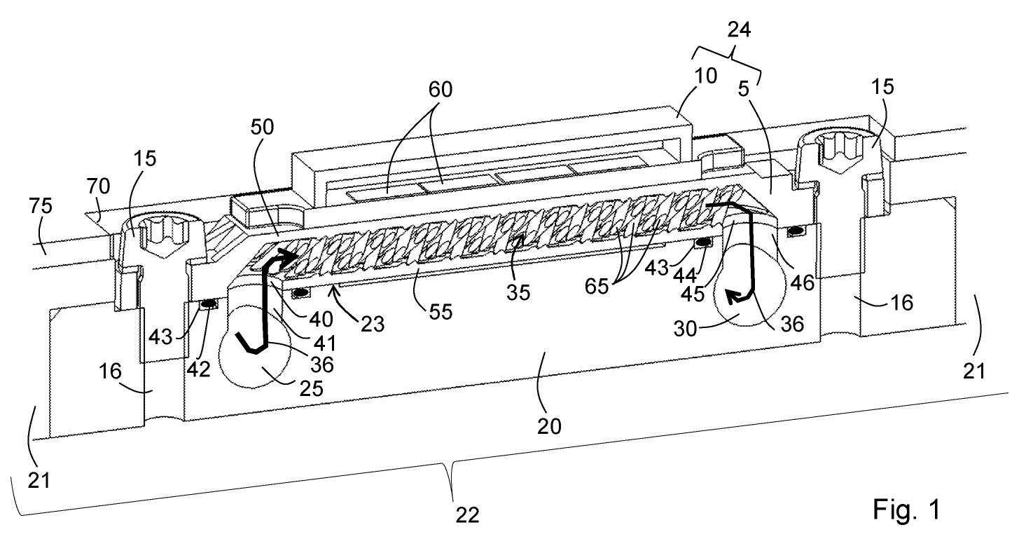

FIG. 1 shows a heat sink 5 according to the embodiments of the present disclosure together with a unit 10 to be cooled in longitudinal section. The unit 10 to be cooled is preferably a semiconductor module, and particularly preferably has a transistor. The heat sink 5 is attached to a distribution unit 20 by means of fastening means 15, preferably screws. Fastening means 16 are provided for this purpose in this receiving device. Within the distribution unit 20, a first flow channel 25 and a second flow channel 30 for the coolant can be seen. The heat sink 5 has a cooling channel 35. Coolant is supplied to the cooling channel 35 of the heat sink 5 via the first flow channel 25 and a coolant inlet 40. A coolant outlet 45 is provided at the end of the cooling channel 35 opposite the coolant inlet 40. The coolant can be discharged via the coolant outlet 45 and the second flow channel 30 after flowing through the cooling channel 40.

The heat sink 5 has a first cooling wall 50 on the side facing the unit 10 to be cooled. On the side of the heat sink 5 facing away from the unit 10 to be cooled, the cooling channel 40 is delimited by a second cooling wall 55, which is opposite the first cooling wall 50. Preferably, the second cooling wall 55 is designed parallel to the first cooling wall 50. The second cooling wall 55 provides at least partial thermal contact between the heat sink 5 and the distribution unit 20.

The unit 10 to be cooled can, for example, be soldered to the heat sink 5 or alternatively be in thermal connection to the heat sink 5 via a thermal paste. The unit 10 to be cooled comprises an arrangement of transistors 60. The heat generated during the operation of the transistors 60 is dissipated via the heat sink 5, which in turn is cooled by the coolant flowing in the cooling channel 35.

Inside the cooling channel 35, a plurality of cooling pins 65 are arranged, which extend from the first cooling wall 50 into the cooling channel 35. Coolant flows around the cooling pins 65 and the cooling pins ensure an improved thermal connection between the heat sink 5 and the coolant flowing through the cooling channel 35.

The heat sink 5 is preferably made of copper. Alternatively, the heat sink can be made of stainless steel, nickel or molybdenum, for example. The distribution unit 20, onto which the heat sink 5 is screwed, preferably consists of or comprises copper. This can be embedded in a carrier unit 21, which preferably consists of or comprises aluminum.

The heat sink 5 is detachably connected to a cooling unit 22. In the example shown in the figures, the cooling unit 22 comprises a distribution unit 20 designed to supply the heat sink 5 with coolant. Furthermore, the cooling unit 22 comprises a carrier unit 21 into which the distribution unit 20 is inserted. The cooling unit 22 has a receptacle 23 into which the heat sink 5 can be detachably inserted. The heat sink 5 is then fastened to the cooling unit 22 by means of at least one fastening means 15, preferably by means of one or more screws. The cooling unit 22 has at least one receiving device 16 for the at least one fastening means 15. To separate the heat sink 5 from the cooling unit 22, at least one fastening means 15 is first detached. The heat sink 5, together with the unit 10 to be cooled attached to it, can then be removed from the receptacle 23 of the cooling unit 22.

The cooling unit 22 comprises a first fluid port 41, which is fluidically connected to the first flow channel 25, and a second fluid port 46, which is fluidically connected to the second flow channel 30.

A 'fluidic connection' is a connection designed to allow a fluid to flow through it.

A 'fluid port' is an opening designed to allow a fluid to pass through it, and to allow a component with a similar opening to be connected to it, so that this fluid can be guided through these openings.

When the heat sink 5 is inserted and subsequently fastened in the receptacle 23, a first fluidic connection is formed between the first fluid port 41 and a coolant inlet 40, and a second fluidic connection is formed between the second fluid port 46 and the coolant outlet 45.

To seal the first fluidic connection, a first sealing ring 42 is arranged in a groove 43 between the cooling unit 22 and the heat sink 5, with the sealing ring 42 completely surrounding the first fluid port 41. Likewise, a second sealing ring 44, completely surrounding the second fluid port 46, is provided at the second fluid port 46 and is arranged in a groove 43 between the cooling unit 22 and the heat sink 5. When the at least one fastening means 15 is fastened, for example when the at least one screw is tightened, the heat sink 5 is pressed against the first fluid port 41 and the first sealing ring 42 as well as against the second fluid port 46 and the second sealing ring 44. As a result of this pressing, a liquid-tight first fluidic connection and a liquid-tight second fluidic connection are formed between the cooling unit 22 and the heat sink 5.

As shown in FIG. 1, a cooling flow 36 can be formed within the cooling apparatus. The coolant flows from the first flow channel 25 via the first fluid port 41 and the coolant inlet 40 into the cooling channel 35. The coolant flows through the cooling channel 35 and via the coolant outlet.

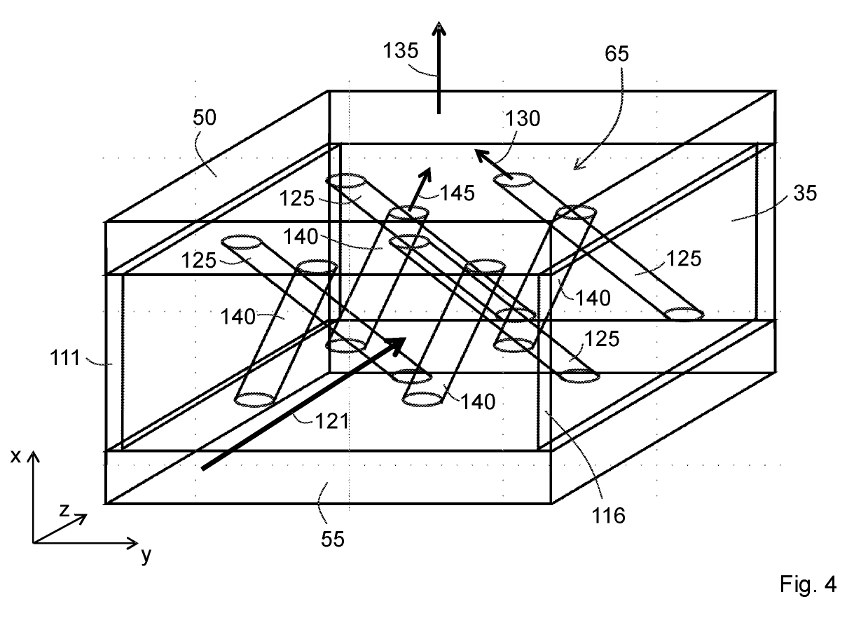

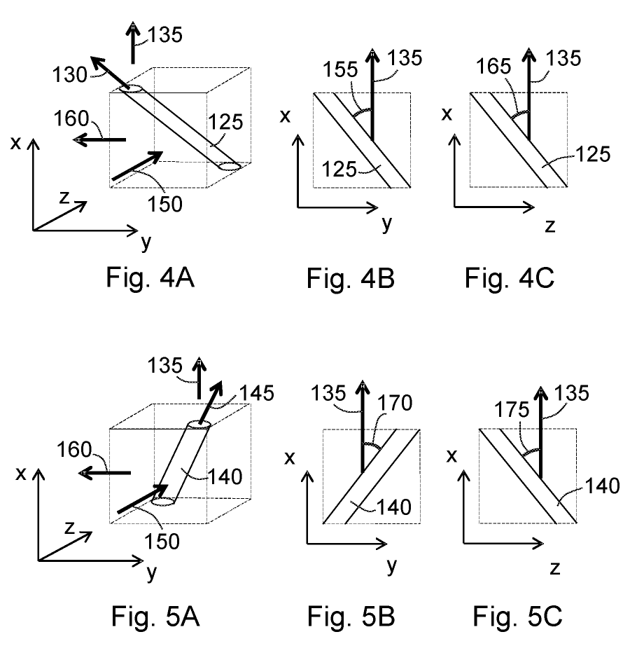

FIG. 1 shows the overlap and in particular the interweaving of the cooling pins of different categories in a viewing direction parallel to the first cooling wall 50. A more detailed description of the overlap and interweaving can also be found further below in the description of FIG. 4.

In FIG. 1, it can also be seen that the unit 10 to be cooled, together with the heat sink 5 arranged below it, is arranged within a first recess 70 of a circuit board 75.

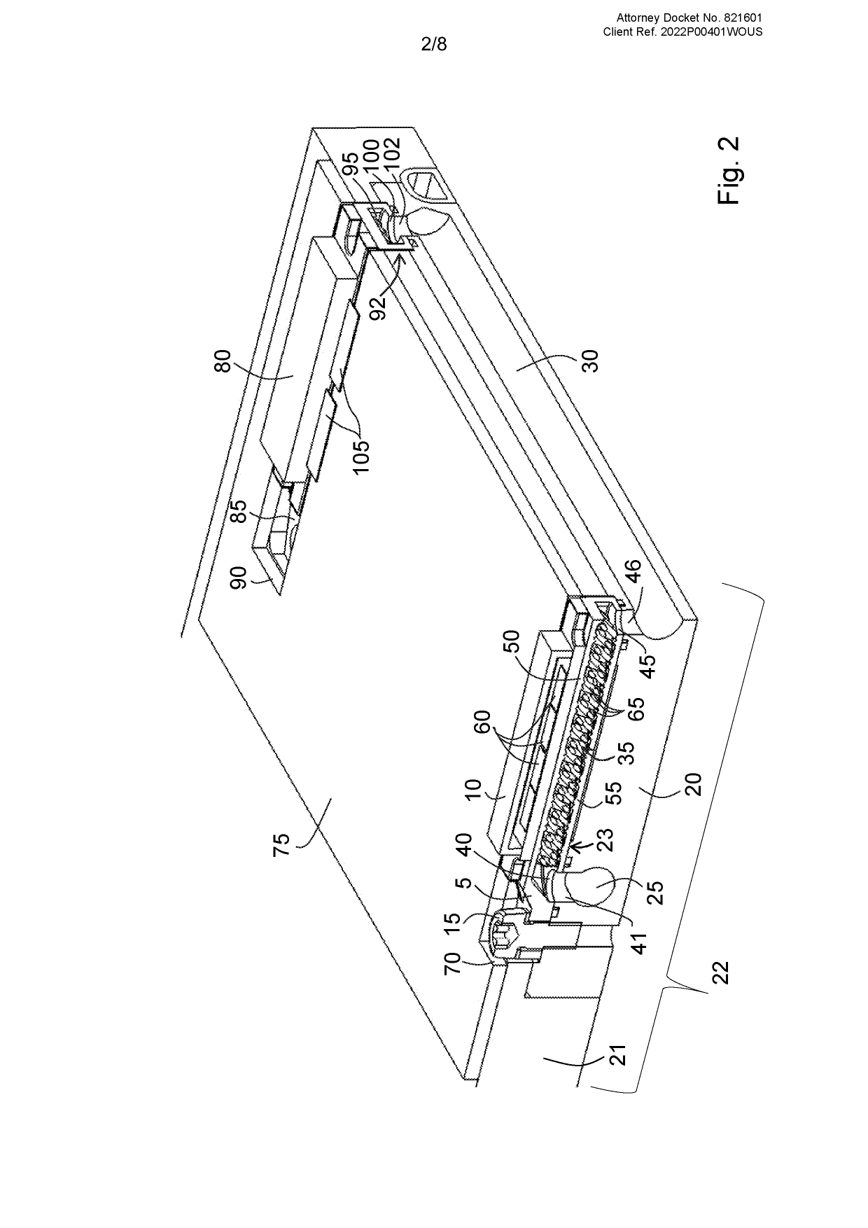

In FIG. 2, the arrangement of the unit 10 to be cooled within the first recess 70 of the circuit board 75 can be clearly seen. FIG. 2 shows the distribution unit 20 and the circuit board 75 attached to the distribution unit 20. Within the first recess 70 of the circuit board 75, the unit 10 to be cooled is arranged with the heat sink 5 located below it, which is shown in longitudinal section in FIG. 2.

The arrangement of transistors 60 can be seen within the unit 10 to be cooled, the waste heat of the transistors being removed by the heat sink 5. The heat sink 5 is screwed to the distribution unit 20 by means of the fastening means 15, preferably by means of the screw. The cooling channel 35 of the heat sink 5 is delimited by the first cooling wall 50 and the second cooling wall 55. Coolant is supplied to the cooling channel 35 via the first flow channel 25 and the coolant inlet 40. The coolant flows through the cooling channel 35 and around the plurality of cooling pins 65. After flowing through the cooling channel 35, the coolant is discharged via the coolant outlet 45 and the second flow channel 30.

In addition to the unit 10 to be cooled, a further unit 80 to be cooled can be seen in FIG. 2 together with a further heat sink 85 arranged below it. The further unit 80 to be cooled is arranged within a further recess 90 provided in the circuit board 75 and the associated further heat sink 85 is inserted into a further receptacle 92 of the cooling unit 22. The further heat sink 85 has a further cooling channel 95, which is connected to the second flow channel 30 via a further coolant outlet 100. Electrical connection terminals 105 can be seen on the further unit 80 to be cooled, which are provided for the formation of electrical connections between the further unit 80 to be cooled and the circuit board 75.

The cooling unit 22 shown in FIG. 2 is designed to supply coolant to a plurality of heat sinks and to discharge the coolant again after it has flowed through the heat sinks. In the example of FIG. 2, the cooling unit 22 is designed to supply coolant both to the heat sink 5 and to the further heat sink 85 and then to discharge it again from both the heat sink 5 and the further heat sink 85. The cooling unit 22 is designed in particular to distribute the coolant evenly among the various heat sinks.

The further heat sink 85 is also fluidically connected to the cooling unit 22 when it is fastened in the further receptacle 92. In the sectional view of FIG. 2, it can be seen that the further cooling channel 95 is connected via the further coolant outlet 100 and the further second fluid port 102 to the second flow channel 30, via which the coolant is discharged.

The circuit board 75 shown in FIG. 2, together with the units 10 and 80 to be cooled that are fastened to the circuit board 75 and the heat sinks 5 and 85, forms a structural unit which, in its entirety, can be placed on and removed again from the cooling unit 22, and which is therefore detachably connectable to the cooling unit 22. When placing this structural unit on the cooling unit 22, the heat sinks 5, 85 attached to the units 10, 80 to be cooled are inserted into the associated receptacles 23, 92 of the cooling unit 22. Subsequently, the heat sinks 5, 85 are fastened to the cooling unit 22 by means of at least one fastening means 15, and fluidic connections for supplying and discharging coolant between the heat sinks 5, 85 and the cooling unit 22 are formed when the heat sinks 5, 85 are fastened to the cooling unit 22. The cooling unit 22 is designed to supply all the heat sinks 5, 85 of the structural unit evenly with coolant and to discharge the coolant after it has flowed through the heat sinks 5, 85.

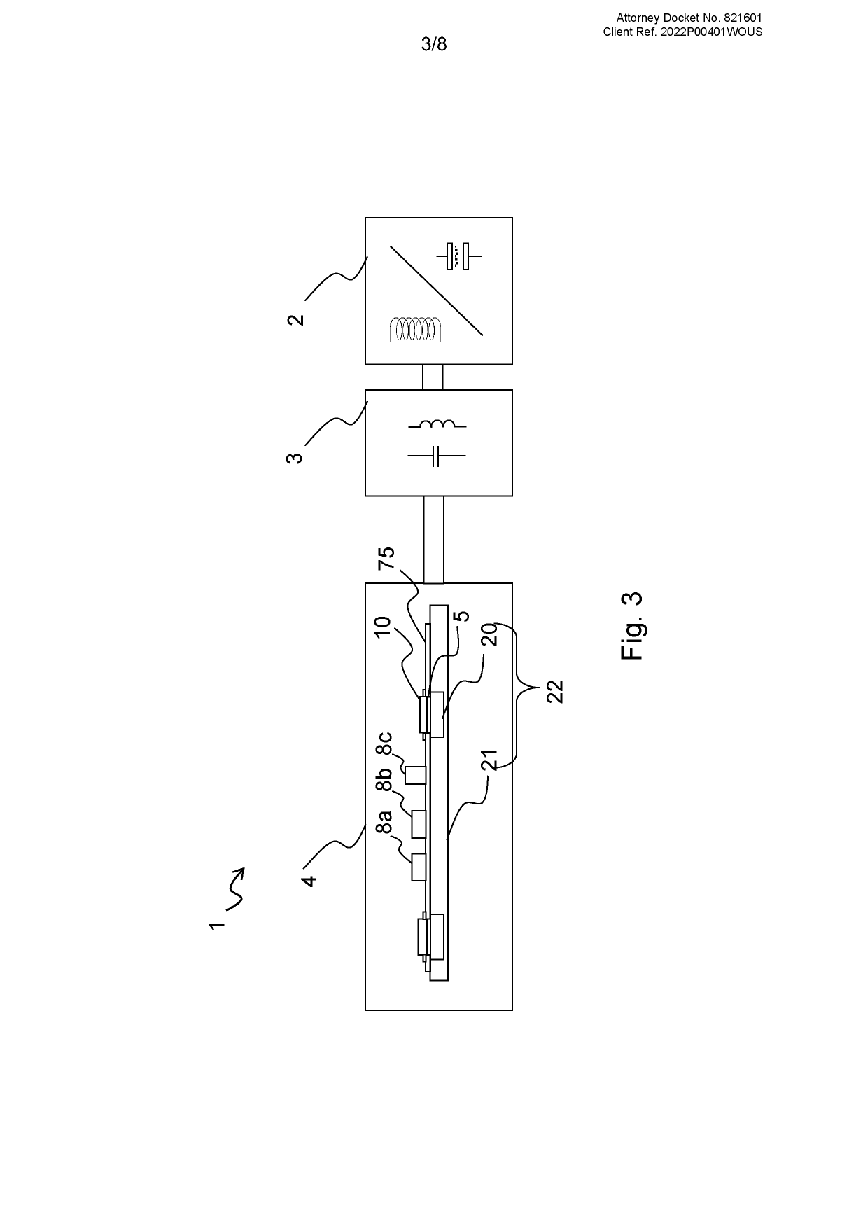

FIG. 3 shows an industrial process assembly 1, preferably a plasma process assembly or a heating assembly. The industrial process assembly 1 has:

an electrical power converter 4,

a load 2, preferably a plasma process or heating process, e.g. an induction or microwave heating process, wherein the load 2 is electrically connected to the electrical power converter 4, so that the electrical power converter 4 can supply the load 2 with the required electrical power,

optionally an additional matching unit 3 is connected between the power converter 4 and the load 2.

The power converter 4 has:

a heat sink 5, as described above and below,

a cooling unit 22, which, as described above and below, has one or more distribution units 20 and a carrier unit 21,

a circuit board 75,

a unit 10 to be cooled, in particular an electric unit, preferably a semiconductor assembly, preferably having a power semiconductor component,

further electronic components 8a, 8b, 8c, wherein the further electronic components 8a, 8b, 8c and the unit 10 to be cooled are arranged on or against a circuit board 75 and are connected to electrical contacts, wherein the unit 10 to be cooled has a fixed, in particular integrally bonded, connection to the heat sink 5.

FIG. 4 shows the cooling channel 35 of the heat sink 5 together with the plurality of cooling pins 65 arranged within the cooling channel 35. The cooling channel 35 is delimited by the first cooling wall 50 facing the first unit 10 to be cooled, the second cooling wall 55 arranged opposite the first cooling wall 50 and by the side walls 111, 116. Preferably, the cooling channel 35 has a substantially rectangular flow cross-section. More preferably, the cross-section of the cooling channel 35 is substantially constant over the entire length of the cooling channel 35. The coolant flow direction 121 within the cooling channel 35 is shown in FIG. 4 by an arrow. As can be seen from the coordinate system x,y,z also shown in FIG. 4, the coolant flows through the cooling channel 35 in the z-direction. Furthermore, it can be seen that the first cooling wall 50 is parallel to the zy-plane. Therefore, the direction 135 perpendicular to the first cooling wall 50 points in the x-direction.

The plurality of cooling pins 65 extends from the first cooling wall 50 into the interior of the cooling channel 40. According to the embodiment shown in FIG. 4, the cooling pins 65 extend into the cooling channel 35, but do not extend to the second cooling wall 55, so that there is a spacing between the ends of the cooling pins 65 facing away from the first cooling wall 50 and the second cooling wall 55. According to an alternative preferred embodiment of the present disclosure, the plurality of cooling pins 65 can extend continuously from the first cooling wall 50 to the second cooling wall 55. Each cooling pin of the plurality of cooling pins 65 is arranged within the cooling channel 35 in such a way that it does not intersect any other cooling pin of the plurality of cooling pins 65. This allows each of the 65 cooling pins to be completely surrounded by coolant.

The plurality of cooling pins 65 comprises cooling pins 125 of a first category, which are oriented in a first inclination direction 130. The first inclination direction 130 is inclined obliquely relative to a direction 135 perpendicular to the first cooling wall 50. In addition, the plurality of cooling pins 65 comprises cooling pins 140 of a second category, which are oriented in a second inclination direction 145. The second inclination direction 145 is inclined obliquely with respect to the direction 135 perpendicular to the first cooling wall 50, the second inclination direction 145 differing from the first inclination direction 130.

FIG. 4 also shows that the plurality of cooling pins 65 overlap at a viewing angle parallel to the cooling wall 50, in particular at a viewing angle of the coolant flow direction 121. "Overlapping" here means that at least one cooling pin 125 of the first category at least partially covers another cooling pin 140 of the second category in the given viewing direction.

FIG. 4 also shows that the plurality of cooling pins 65 are interweaved at a viewing angle parallel to the cooling wall 50, in particular at a viewing angle of the coolant flow direction 121. "Interweaved" here means that at least one first cooling pin 125 of the first category at least partially covers a second cooling pin 140 of the second category in the given viewing direction, and that the first cooling pin itself is also at least partially covered by a further cooling pin 140 of the second category in the given viewing direction.

The cooling pins 65 arranged within the cooling channel are preferably produced by means of an additive manufacturing process, preferably by means of selective laser melting.

FIGS. 4A, 4B, and 4C show, using projection views, how the cooling pins 125 of the first category are oriented in an obliquely inclined manner within the cooling channel 35.

FIG. 4A shows a cooling pin 125 of the first category in oblique view. The cooling pin 125 is oriented in a first inclination direction 130 relative to a direction 135 perpendicular to the first cooling wall 50. Together with the cooling pin 125 of the first category, a coordinate system is shown in FIG. 4A which corresponds to the coordinate system of FIG. 4. First, the cooling pin 135 of the first category is viewed in a first projection direction 150. The first projection direction 150 corresponds to the flow direction of the coolant, i.e. the z-direction. When viewing the cooling pin 125 of the first category in the first projection direction 150, one arrives at the view shown in FIG. 4B in a first projection plane perpendicular to the first projection direction 150. This first projection plane is the xy-plane. It can be seen that the cooling pin 125 of the first category is inclined obliquely at a first angle 155 in this first projection plane relative to the perpendicular direction 135. The cooling pin 125 is inclined counterclockwise relative to the perpendicular direction 135, and therefore the first angle 155 has a negative value in the range between 0° and -90°.

Next, the cooling pin 125 is viewed in a second projection direction 160, which is also shown in FIG. 4A. This second projection direction 160 is orthogonal both to the flow direction of the coolant and the direction 135 perpendicular to the first cooling wall 50. When viewing the cooling pin 125 in the second projection direction 160, one arrives at the view shown in FIG. 4C in a second projection plane perpendicular to the second projection direction 160. This second projection plane is the xz-plane. FIG. 4C shows that the cooling pin 125 of the first category is oriented in an obliquely inclined manner in this second projection plane at a second angle 165 to the perpendicular direction 135. The cooling pin 125 is inclined counterclockwise relative to the perpendicular direction 135, and therefore the second angle 165 has a negative value in the range between 0° and -90°.

FIGS. 4A to 4C show that the cooling pins 125 of the first category are oriented in an obliquely inclined manner with respect to the perpendicular direction 135 in two respects. Both when viewed in the first projection direction 150 and when viewed in the second projection direction 160, the cooling pins 125 of the first category are oriented in an obliquely inclined manner with respect to the perpendicular direction 135.

FIGS. 5A, 5B and 5C show, using projection views, how the cooling pins 140 of the second category are oriented in an obliquely inclined manner within the cooling channel 35.

FIG. 5A shows the orientation of a cooling pin 140 of the second category in an oblique view together with a coordinate system that corresponds to the coordinate system shown in FIG. 4. The z-direction indicates the flow direction of the coolant. The cooling pin 140 is oriented in a second inclination direction 145 relative to a direction 135 perpendicular to the first cooling wall 50. When viewing the cooling pin 140 of the second category in the first projection direction 150, which corresponds to the flow direction of the coolant, then one obtains the view shown in FIG. 5B in a first projection plane perpendicular to the first projection direction 150. This first projection plane is the xy-plane. FIG. 5B shows that the cooling pin 140 of the second category, when viewed in the first projection direction 150, is inclined obliquely at a third angle 170 relative to the perpendicular direction 135. Since the cooling pin 140 is inclined obliquely clockwise, the third angle 170 is a positive angle in the range between 0° and 90°.

When viewing the cooling pin 140 of the second category in the direction of the second projection direction 160, one arrives at the view shown in FIG. 5C in a second projection plane perpendicular to the second projection direction 160. This second projection plane is the xz-plane. FIG. 5C shows that the cooling pin 140 of the second category, when viewed in the second projection direction 160, is inclined obliquely at a fourth angle 175 relative to the perpendicular direction 135, namely inclined obliquely counterclockwise. Therefore, the fourth angle 175 is a negative angle in the range between 0° and 90°.

The cooling pin 140 of the second category shown in FIGS. 5A to 5C is also a cooling pin inclined in two respects, which is inclined obliquely relative to the perpendicular direction 135 both when viewed in the first projection direction 150 and when viewed in the second projection direction 160.

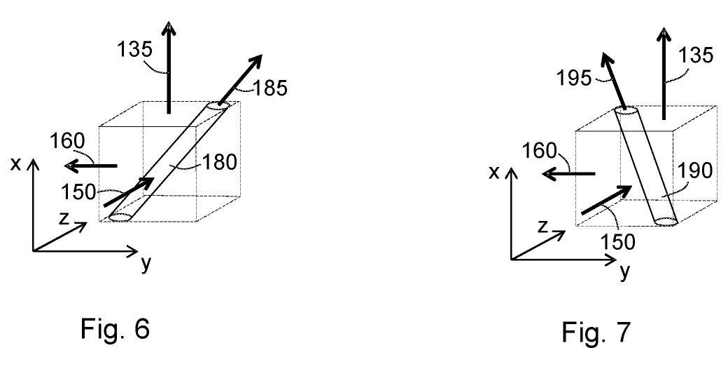

FIG. 6, as a further example, shows an oblique view of a cooling pin 180 of a third category together with the coordinate system of FIG. 4, wherein the cooling pin 180 of the third category is oriented in an obliquely inclined manner relative to the perpendicular direction 135 in a third inclination direction 185. When the cooling pin 180 of the third category is viewed in the first projection direction 150 and in the second projection direction 160, it turns out that the cooling pin 180 of the third category is oriented in an obliquely inclined manner in the first projection plane at a positive angle in the range between 0° and 90° with respect to the perpendicular direction 135 and is also oriented in an obliquely inclined manner in the second projection plane at a positive angle in the range between 0° and 90° with respect to the perpendicular direction 135.

FIG. 7, as a further example, shows an oblique view of a cooling pin 190 of a fourth category together with the coordinate system of FIG. 4, wherein the cooling pin 190 of the fourth category is oriented in an obliquely inclined manner relative to the perpendicular direction 135 in a fourth inclination direction 195. When the cooling pin 190 of the fourth category is viewed in the first projection direction 150 and in the second projection direction 160, it turns out that the cooling pin 190 of the fourth category is oriented in an obliquely inclined manner in the first projection plane at a negative angle in the range between 0° and 90° with respect to the perpendicular direction 135 and is oriented in an obliquely inclined manner in the second projection plane at a positive angle in the range between 0° and 90° with respect to the perpendicular direction 135.

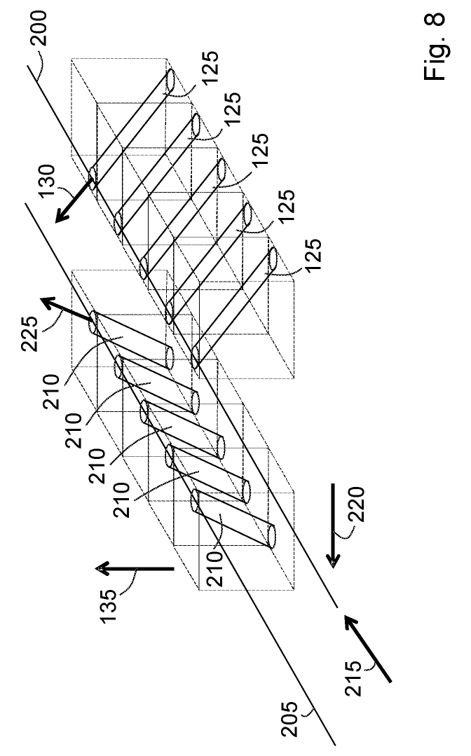

FIG. 8 shows a preferred embodiment of the present disclosure. According to this embodiment, a plurality of cooling pins 125 of the first category are arranged along a first straight line 200 which extends along the first cooling wall 50. Preferably, the cooling pins 125 of the first category are arranged with regular spacing along the first straight line 200. Parallel to the first straight line 200, a second straight line 205 runs along the first cooling wall 50 with a certain spacing with respect to the first straight line 200. A plurality of cooling pins 210 which are mirror-inverted with respect to the cooling pins 125 of the first category are arranged along the second straight line 205. Preferably, the cooling pins 210 which are mirror-inverted with respect to the cooling pins 125 of the first category are arranged with regular spacing along the second straight line 205.

The cooling pins 125 of the first category are arranged in a manner oriented in a first inclination direction 130, the first inclination direction 130 being inclined obliquely relative to the direction 135 perpendicular to the first cooling wall 50.

Viewed in a third projection direction 215, which corresponds to the direction of the first straight line 200, the cooling pins 125 of the first category are arranged in an obliquely inclined manner with respect to the perpendicular direction 135. Even when viewed in a fourth projection direction 220, which is orthogonal both to the third projection direction 215 and to the perpendicular direction 135, the cooling pins 125 of the first category are oriented in an obliquely inclined manner relative to the perpendicular 135. The cooling pins 125 of the first category are therefore oriented in obliquely inclined manner in two respects. Firstly, when viewed in the third projection direction 215, they are inclined obliquely relative to the perpendicular direction 135, and secondly, when viewed in the fourth projection direction 220, they are inclined obliquely relative to the perpendicular direction 135.

The cooling pins 210 which are mirror-inverted with respect to the cooling pins 125 are oriented in an inclination direction 225 which is mirror-inverted with respect to the first inclination direction 130. The following explains what is meant by a mirror-inverted inclination direction. Viewed in the third projection direction 215, the mirror-inverted cooling pins 210 are inclined relative to the perpendicular direction 135 in the opposite direction compared to the cooling pins 125 of the first category. In the fourth projection direction 220, however, the mirror-inverted cooling pins 210 are oriented in an obliquely inclined manner at the same angle relative to the perpendicular direction 135 as the cooling pins 125 of the first category.

Consequently, a mirror-inverted orientation of the mirror-inverted cooling pins 210 means that, when viewed in the third projection direction 215, they are inclined at the opposite angle relative to the perpendicular direction 135 as the cooling pins 125 of the first category, but when viewed in the fourth projection direction, they are oriented in an inclined manner in the same direction as the cooling pins 125 of the first category.

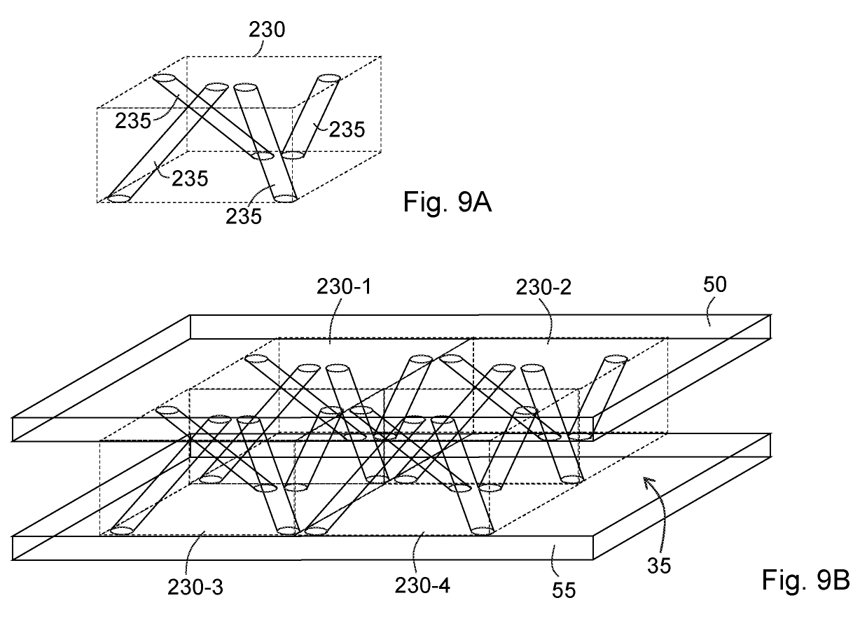

FIGS. 9A and 9B show a further preferred embodiment of the present disclosure, in which the arrangement of the cooling pins within the cooling channel 35 is determined by means of a unit cell 230. FIG. 9A shows the structure of the unit cell 230. A second plurality of cooling pins 235 is arranged within the unit cell 230. The cooling pins 235 arranged within the cooling unit cell 230 are designed to extend from the first cooling wall 50 into the interior of the cooling channel 35. The cooling pins of the second plurality of cooling pins 235 within the unit cell 230 are arranged such that a cooling pin 235 does not intersect any other cooling pin of the second plurality of cooling pins 235. The cooling pins of the second plurality of cooling pins 235 can, for example, comprise one or more cooling pins 125 of the first category and/or one or more cooling pins 140 of the second category.

FIG. 9B shows the cooling channel 35, which is delimited by the first cooling wall 50 and the second cooling wall 55. A plurality of identical unit cells 230-1 to 230-4 of the type shown in FIG. 9A are arranged within a sub-region of the cooling channel 35. Preferably the unit cells 230-1 to 230-4 are arranged adjacent to each other, preferably in a plurality of rows and/or a plurality of columns. The height of a unit cell 230 preferably corresponds to the height of the cooling channel 35. The second plurality of cooling pins 235 arranged within each unit cell 230-1 to 230-4 extends from the first cooling wall 50 into the interior of the cooling channel 35.

According to a first embodiment, the cooling pins of the second plurality of cooling pins 235 do not extend to the second cooling wall 55, so that there is a certain spacing between the ends of the cooling pins 235 facing away from the first cooling wall 50 and the second cooling wall 55. According to an alternative preferred embodiment, the cooling pins of the second plurality of cooling pins 235 extend within the cooling channel 35 from the first cooling wall 50 continuously to the second cooling wall 55.

FIGS. 9a and 9b also show the overlap and in particular the interweaving of the cooling pins of different categories in a viewing direction parallel to the first cooling wall 50.

In the embodiment shown in FIGS. 9A and 9B, the unit cell 230 serves as a basic design unit with which the arrangement of the cooling pins within the cooling channel 35 can be determined with minimal effort.

The features disclosed in the above description and the drawings can be important both individually and in any combination for the realization of the present disclosure in its various embodiments.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

Patent claims:

1. A heat sink for cooling an electric unit to be cooled, the heat sink comprising:
a cooling channel through which cooling liquid is configured to flow in an intended flow direction,
wherein the cooling channel has a first cooling wall on a side of the cooling channel facing the electric unit to be cooled; and
a plurality of cooling pins arranged in the cooling channel or in a sub-region of the cooling channel, the plurality of cooling pins extending from the first cooling wall into the cooling channel,
wherein the plurality of cooling pins comprises at least one cooling pin of a first category which is oriented in a first inclination direction, the first inclination direction being inclined obliquely relative to a perpendicular to the first cooling wall, and
wherein the plurality of cooling pins are arranged such that each respective cooling pin of the plurality of cooling pins does not intersect any other cooling pin of the plurality of cooling pins.

2. The heat sink according to claim 1, wherein:
viewed in a first projection direction, the first inclination direction is inclined obliquely with respect to the perpendicular to the first cooling wall, the first projection direction being the intended flow direction of the cooling liquid, and
viewed in a second projection direction, the first inclination direction is inclined obliquely with respect to the perpendicular to the first cooling wall, the second projection direction being orthogonal both to the intended flow direction and to the perpendicular to the first cooling wall.

3. The heat sink according to claim 2, wherein, viewed in the first projection direction, the first inclination direction in a first projection plane is inclined at a first angle with respect to the perpendicular to the first cooling wall, and wherein the first angle is a positive or negative angle in a range between 0° and 90°.

4. The heat sink according to claim 3, wherein, viewed in the second projection direction, the first inclination direction in a second projection plane is inclined at a second angle with respect to the perpendicular to the first cooling wall, wherein the second angle is a positive or negative angle in the range between 0° and 90°.

5. The heat sink according to claim 1, wherein the plurality of cooling pins comprises at least one cooling pin of a second category, which is oriented in a second inclination direction, the second inclination direction being inclined obliquely relative to the perpendicular to the first cooling wall, wherein the second inclination direction is different from the first inclination direction.

6. The heat sink according to claim 5, wherein:
viewed in a first projection direction, the second inclination direction is inclined obliquely with respect to the perpendicular to the first cooling wall, the first projection direction being the intended flow direction of the cooling liquid, and
viewed in a second projection direction, the second inclination direction is inclined obliquely with respect to the perpendicular to the first cooling wall, the second projection direction being orthogonal both to the intended flow direction and to the perpendicular to the first cooling wall.

7. The heat sink according to claim 6, wherein the plurality of cooling pins comprises a plurality of cooling pins of the first category arranged along a first straight line that runs along the first cooling wall.

8. The heat sink according to claim 7, wherein:
viewed in a third projection direction, the first inclination direction is inclined obliquely at a fifth angle with respect to the perpendicular to the first cooling wall, the third projection direction being the direction of the first straight line, and
viewed in a fourth projection direction, the first inclination direction is inclined obliquely at a sixth angle with respect to the perpendicular to the first cooling wall, the fourth projection direction being orthogonal both to the first straight line and to the perpendicular to the first cooling wall.

9. The heat sink according to claim 8, wherein the plurality of cooling pins comprises a plurality of cooling pins that are mirror-inverted with respect to the cooling pins of the first category and that are oriented in an inclination direction that is mirror-inverted with respect to the first inclination direction, and wherein the plurality of cooling pins that are mirror-inverted with respect to the cooling pins of the first category are arranged along a second straight line that runs parallel to the first straight line along the first cooling wall.

10. The heat sink according to claim 9, wherein:
viewed in a third projection direction, the inclination direction that is mirror-inverted with respect to the first inclination direction is inclined obliquely at a seventh angle with respect to the perpendicular to the first cooling wall, the third projection direction the direction of the first straight line,
viewed in a fourth projection direction, the inclination direction that is mirror-inverted with respect to the first inclination direction is inclined obliquely at an eighth angle with respect to the perpendicular to the first cooling wall, the fourth projection direction being orthogonal both to the first straight line and to the perpendicular to the first cooling wall, and
the seventh angle corresponds to the fifth angle with a negative sign and the eighth angle corresponds to the sixth angle.

11. The heat sink according to claim 1, wherein the cooling channel has a second cooling wall on a side of the cooling channel opposite the first cooling wall.

12. The heat sink according to claim 11, wherein each of the plurality of cooling pins extends continuously from the first cooling wall to the second cooling wall.

13. The heat sink according to claim 1, wherein the heat sink is a micro heat sink and wherein the electric unit to be cooled is an electronic component.

14. The heat sink according to claim 1, wherein the heat sink comprises copper.

15. The heat sink according to claim 1, wherein the plurality of cooling pins are configured to be formed by selective laser melting.

16. The heat sink according to claim 5, wherein the plurality of cooling pins are arranged such that the at least one cooling pin of the first category overlaps with the at least one cooling pin of the second category at a viewing angle of a coolant flow direction parallel to the cooling wall.

17. The heat sink according to claim 16, wherein the plurality of cooling pins are arranged such that the at least one cooling pin of the first category is interweaved with two cooling pins of the second category at a viewing angle of the coolant flow direction parallel to the cooling wall.

18. An electrical power converter for an industrial process assembly, preferably a plasma process assembly or a heating assembly, having:
the heat sink according to claim 1; a circuit board;
the electric unit to be cooled; and
further electronic components,
wherein the further electronic components and the electric unit to be cooled are arranged on or against the circuit board and are connected by electrical contacts, and
wherein the electric unit to be cooled has a fixed, integrally bonded connection to the heat sink.

19. A method for designing a heat sink for cooling a unit to be cooled, wherein the heat sink has a cooling channel through which coolant can flow in an intended flow direction, the cooling channel having a first cooling wall on a side of the cooling channel facing an electric unit to be cooled, the method comprising:
arranging a plurality of cooling pins in the cooling channel, each of the plurality of cooling pins extending from the first cooling wall into the cooling channel,
wherein the plurality of cooling pins comprises at least one cooling pin of a first category that is oriented in a first inclination direction inclined obliquely relative to a perpendicular to the first cooling wall, and
wherein the plurality of cooling pins are arranged such that each respective cooling pin of the plurality of cooling pins does not intersect any other cooling pin of the plurality of cooling pins.

20. A method for producing a heat sink for cooling an electric unit to be cooled, wherein the heat sink has a cooling channel through which coolant can flow in an intended flow direction, the cooling channel having a first cooling wall on a side of the cooling channel facing the electric unit to be cooled, the method comprising:
producing a plurality of cooling pins within the cooling channel by an additive process, each of the plurality of cooling pins extending from the first cooling wall into the cooling channel,
wherein the plurality of cooling pins comprises at least one cooling pin of a first category that is oriented in a first inclination direction inclined obliquely relative to a perpendicular to the first cooling wall, and
wherein the plurality of cooling pins are arranged such that each respective cooling pin of the plurality of cooling pins does not intersect any other cooling pin of the plurality of cooling pins.
